(19) United States
(12) Patent Application Publication
(10) Pub. No.: US 2009/0229660 A1
(43) Pub. Date: Sep. 17, 2009

(54) SOLAR CELL AND METHOD FOR MANUFACTURING THE SAME

(75) Inventors: Teruo TAKIZAWA, Matsumoto (JP); Hideki TANAKA, Chino (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/370,734

(22) Filed: Feb. 13, 2009

(30) Foreign Application Priority Data
Mar. 11, 2008 (JP) 2008-060860

(51) Int. Cl. H01L 31/00; B05D 5/12

(52) U.S. Cl. 136/256; 427/74

(57) ABSTRACT

A solar cell includes a pair of opposing substrates of which at least one is transparent, conductive films that have different work function and are respectively provided to opposing faces of the pair of substrates, a silicon layer nipped between the conductive films, and an insulative partition wall provided between the pair of substrates to surround a side face of the silicon layer.

### BACKGROUND

1. Technical Field

The present invention relates to a solar cell and a method for manufacturing the same.

2. Related Art

Solar cells have been extensively developed as eco-friendly technique. Solar cells are classified into mainly a silicon-based type and a chemical compound semiconductor-based type depending on a kind of a semiconductor used, and the former solar cells are classified into a crystalline silicon-based type and an amorphous silicon-based type. Further, the crystalline silicon-based type solar cells are subclassified into a monocrystalline silicon-based type and a polycrystalline silicon-based type.

Monocrystalline silicon-based type solar cells have been developed from many years ago, and include, for example, a cell having a pn junction or pin junction formed on a monocrystalline silicon and a cell having a Schottky junction formed on a monocrystalline silicon. While the monocrystalline silicon type solar cell is superior in a conversion efficiency or reliability, there is a problem that the manufacturing cost is high.

To solve the above problem, a cell in which fine polycrystalline silicon or amorphous silicon is laminated on a substrate made of low cost glass or the like is proposed. While the above type may have a large area and is suitable for mass production, there is a problem that the conversion efficiency of light is lower as compared to a monocrystalline silicon type.

As one of the methods for improving the conversion efficiency, it is proposed that irregularities having a height difference not less than a few micron meter are formed on a light-incident face, and incident light is multiply reflected to be trapped in a solar cell at a high efficiency, thereby using a so-called light-trapping effect. JP-A-05-267702 is an example of related art.

There is provided a method using a plasma CVD device as one for forming amorphous silicon on a substrate. The method is disclosed in JP-A-06-283435, which is another example of related art. However, the above method has a problem that it is difficult to control a characteristic and a film thickness of an amorphous silicon film formed on a substrate so that it is hard to form a semiconductor layer satisfying a condition of a solar cell.

Further, a hybrid type (HIT type) solar cell formed by laminating crystalline silicon and amorphous silicon on a substrate is proposed. While a conversion efficiency of light of the above type is higher as compared to a typical polycrystalline silicon type and is superior in temperature characteristic, there is a problem that the manufacturing process is cumbersome.

On the other hand, as a solar cell with the use of a chemical compound semiconductor, one with the use of a chemical compound semiconductor material in a III-V or II-VI group, e.g., GaAs or CdTe, or a dye-sensitized type one with the use of an organic material is proposed. Anyone of them is expected to have a high performance, but has high manufacturing cost and bad weatherability.

### SUMMARY

An advantage of the present invention is to provide a solar cell having a structure which can be manufactured in a simple manufacturing process at low cost and to provide a method for manufacturing a solar cell.

A solar cell according to a first aspect of the invention includes a pair of opposing substrates of which at least one is transparent, conductive films that have different work function and are respectively provided to opposing faces of the pair of substrates, a silicon layer nipped between the conductive films, and an insulative partition wall provided between the pair of substrates to surround a side face of the silicon layer.

According to the solar cell of the invention, with the use of the insulative partition wall, it is possible to maintain a distance between the substrates constant, thereby preventing the conductive film and transparent conductive film from being in contact with each other. As a result, it is possible to achieve the highly reliable solar cell.

In addition, with the use of the insulative partition wall, the silicon layer is protected from its side to prevent the deformation, thereby improving the mechanical strength of the solar cell.

A method for manufacturing a solar cell according to a second aspect of the invention includes processes of forming a conductive film on a first face of a substrate, forming an insulative partition wall so as to surround a peripheral edge of the conductive film, injecting a liquid silicon composition in a region surrounded by the insulative partition wall on the first face of the substrate, forming a transparent conductive film on a second face of a transparent substrate, placing the transparent substrate on the liquid silicon composition so as to allow the transparent conductive film to be opposed to the conductive film, and heating the liquid silicon composition.

According to the method for manufacturing a solar cell of the invention, a region surrounded by the insulative partition wall is formed on one of the substrate, the liquid silicon composition is injected to the region, and then the heat treatment is applied to the silicon layer. As a result, it is possible to manufacture the solar cell by the extremely simple method as compared to a heretofore typical method, thereby manufacturing the solar cell with a large area at low cost.

In addition, since the side face of the formed silicon layer is covered with the insulative partition wall and the distance between the substrates can be maintained constant, it is possible to prevent the substrate with the large area from being bent and to prevent a short circuit between the electrodes nipping the silicon layer, thereby manufacturing the highly reliable solar cell. As the silicon layer is protected by the insulative partition wall, it is possible to obtain the solar cell with high strength.

A metallic material having a high reflectivity and a work function which is greater than a Fermi level of the silicon layer formed by solidifying the liquid silicon composition, may be preferably used as the conductive film.

According to the above structure, it is possible to form a cathode capable of surely capturing a positive hole generated in the silicon layer serving as a light reception layer. With the use of the metallic material having a high reflectivity, light which is not absorbed by the silicon layer can be reflected by the conductive film to be incident on the silicon layer again to be absorbed, thereby efficiently utilizing the light.

A material having a band gap of 1 eV or more and a work function which is smaller than the Fermi level of the silicon layer formed by solidifying the liquid silicon composition, may be preferably used as the transparent conductive film.

According to the above structure, it is possible to form an anode capable of surely capturing an electron generated in the silicon layer serving as the light reception layer. In addition, when the material having the band gap of 1 eV is used, visible light can be sufficiently transmitted through the material.

A droplet discharge method may be used in the event of injecting the liquid silicon composition.

According to the above structure, as the liquid silicon composition can be subjected to the patterning directly and in a non-contact manner, so that a necessary, minimum amount of the liquid silicon composition is used for a necessary region, thereby extremely saving resources and providing the simple, inexpensive solar cell.

### BRIEF DESCRIPTION OF THE DRAWINGS

The invention will be described with reference to the accompanying drawings, wherein like numbers reference like elements.

FIG. 1 is a schematic cross-sectional view showing a solar cell according to a first embodiment of the invention.

FIG. 2 is a schematic view illustrating a band diagram of the solar cell of the invention.

FIGS. 3A through 3E are schematic cross-sectional views showing a manufacturing method according to an embodiment of the invention.

FIG. 4 is a schematic cross-sectional view showing a solar cell according to a second embodiment of the invention.

FIG. 5 is a schematic cross-sectional view showing a solar cell according to a third embodiment of the invention.

### DESCRIPTION OF EXEMPLARY EMBODIMENTS

The preferred embodiments of the solar cell and the method for manufacturing the solar cell of the invention will be described with reference to the accompanying drawings. Each of the embodiments described below is shown by way of an example, not intended to limit the invention, and able to be modified within the technical scope of the invention. It should be noted that different scales are used for the layers and members in the drawings, so that the layers and members can be recognized.

[Solar Cell]

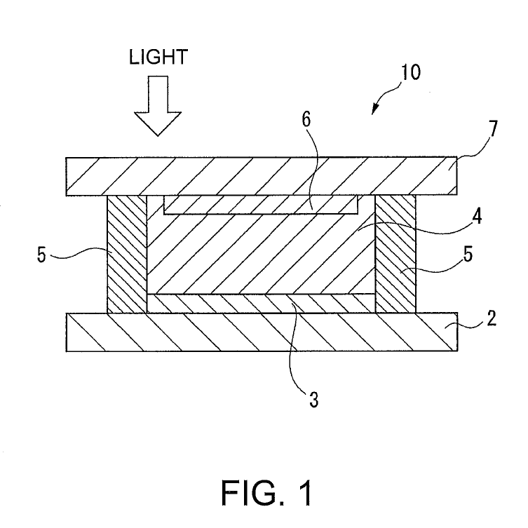

First, a structure of a solar cell of the invention is described below with reference to FIG. 1. FIG. 1 is a schematic cross-sectional view showing an embodiment of a solar cell 1 obtained by a manufacturing method of the invention. The solar cell 1 is configured of a substrate 2, a cathode 3 (conductive film) formed on a top face of the substrate 2, a silicon layer 4 formed on a top face of the cathode 3, an insulative partition wall 5 formed so as to surround side faces of the silicon layer 4 and cathode 3, an anode 6 (transparent conductive film) disposed to be opposed to the cathode 3 with the insulative partition wall 5 and silicon layer 4 therebetween, and a transparent substrate 7 provided on a top face of the anode 6.

The substrate 2 serves as a support member for the conductive film to be the cathode 3 and the whole part of the solar cell 1. The transparent substrate 7 serves as a support member of the transparent conductive film to be the anode 6. Each of the supports is formed of a plate like member. The substrate 2 is formed of any of various kinds of materials such as, for example, glass, metal, ceramic and plastic materials, and may be formed of an opaque material or a transparent material like the transparent substrate 7.

As to the solar cell 1 of this embodiment shown in FIG. 1, since the solar cell 1 is used by inputting light from the side of the transparent substrate 7, the material of the transparent substrate 7 in the materials which can be used for the substrate 2, is not specifically limited, but has a transparency in a wavelength region of the incident light. The material can be non-color transparent, colored transparent or semitransparent so that a glass or plastic material can be preferably used. In addition, each of the substrate 2 and transparent substrate 7 may have a flexibility. However, each of the substrates is necessary to have a heat-resistance durable to process temperature in the event of forming the silicon layer 4.

The cathode 3 is formed on the top face of the substrate 2 and functions as the cathode for capturing a positive hole generated on the silicon layer 4 to be a light reception layer. Particularly, it is preferable that the conductive film 3 is formed of a material having a work function greater than a Fermi level of the silicon layer 4. That is, a material having a Fermi level (which is normally a negative value, but indicated in an absolute value, here) not less than 4.61 eV of, for example, intrinsic midgap energy of silicon, is used for the conductive film 3.

In addition, when a metallic material having a high reflectivity is used, the incident light which is not absorbed by the silicon layer 4, can be reflected by the cathode 3 to be incident on the silicon layer 4, and then absorbed again by the silicon layer 4 so that it is preferable that the incident light can be used highly efficiently. As a material for the above, metals such as Pt, Au, Ni, Ir, and Co and alloys thereof can be listed. In this embodiment, Pt having a work function of 5.29 eV and a high reflectivity is used.

The insulative partition wall 5 is a partition member formed so as to surround the side faces of the cathode 3 and silicon layer 4. The insulative partition wall 5 functions to maintain a distance between the substrate and the transparent substrate 7 constant. As a result, it is possible to prevent the conductive film 3 from being in contact with the transparent conductive film 7 and to control a film thickness of the silicon layer 4.

In addition, the insulative partition wall 5 protects the silicon layer 4 to prevent it from being deformed, thereby improving the mechanical strength of the solar cell. Particularly, in a solar cell having a large area, it is possible to prevent the substrate 2 and transparent substrate 7 from being bent, resulting in advantage to the invention.

The insulative partition wall 5 may be formed of not only a material of various kinds of resins such as, for example, a polycarbonate resin, an ultraviolet-curable resin, a thermally curable resin, an epoxy resin, a polyimide resin, but also a glass or a ceramic, and a combination of any of the above materials can be used. In this embodiment, the insulative partition wall 5 with a thickness of approximately 1 μm formed of TEOS (tetraethylorthosilicate) of silicon oxide is used.

The silicon layer 4 is formed (described later in detail) such that after a region surrounded by the insulative partition wall 5 is filled with a liquid silicon composition, a heat treatment is applied to the liquid silicon composition. The silicon layer 4 serves as a light receptive layer that generates an electron and a positive hole by receiving incident light such as sunlight. It is preferable that the film thickness of the silicon layer 4 is not less than at least 1 μm.

That is because a permeable length (absorption length) L_{α} of a depth that incident light permeates the silicon layer 4 is 1 μm (in a case of, for example, visible light with a wavelength of approximately 500 nm). To describe that in detail, assuming that the incident light is absorbed in the silicon layer 4 as the intensity is constant, the absorption length L_{α} becomes an inverse number of an absorption coefficient α₀ of the silicon layer 4 as an absorption medium of the incident light. The intensity of the incident light at a time it permeates the silicon layer 4 by the absorption length L_{α} is e⁻¹ which is reduced by 37% from its original strength so that the use of more than that is unrealistic. When the absorption coefficient α₀ of the silicon is represented by a formula: α₀=1×10⁴ cm⁻¹, the absorption length L_{α} becomes 1 μm so that it is most efficient that the film thickness of the silicon layer 4 is made to be more than the absorption length L_{α}.

The anode 6 is formed on a lower face of the transparent substrate 7 and is adapted to capture an electron generated by the silicon layer 4. Particularly, it is preferable that the transparent conductive film constituting the anode 6 is formed of a material having a work function smaller than the Fermi level of the silicon layer 4 contrary to a case of the conductive film constituting the cathode 3. That is, it is preferable that the Fermi level (which is normally a negative value, but indicated in an absolute value, here) of the transparent conductive film is not greater than 4.61 eV of, for example, intrinsic midgap energy of silicon.

In addition, in order to allow the incident light to permeate the silicon layer 4, the anode 6 is necessary to be substantially transparent with respect to the incident light. As to the above material, ZnO, In₂O₃, SnO₂, and CdO can be listed. When a material having a band gap not less than 3.1 eV is used, it is possible to allow visible light (wavelength is not less than 0.4 μm) to sufficiently permeate the material. In this embodiment, ZnO having a work function of 3.4 eV is used.

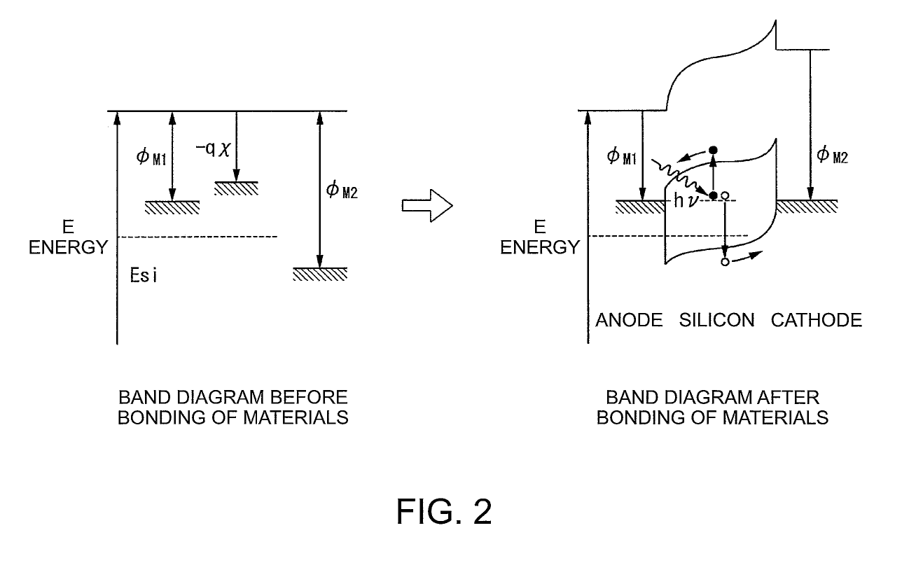

FIG. 2 illustrates a band diagram of the solar cell of the invention. Φ_{M1} represents a work function of the transparent conductive film 6 to be the anode and Φ_{M2} represents a work function of the conductive film 3 to be the cathode. In FIG. 2, E_{Si} represents the Fermi level (preferably intrinsic midgap energy) of silicon. When the materials are bonded with each other, the band diagram is deformed, and then bending of a band (band bending) occurs in the silicon film. Further, when a positive bias is applied to the anode and a negative bias is applied to the cathode, the bending of the band is increased so that a pair of positive hole and electron generated by radiation of the light can be readily separated from each other. As a result, it is possible to achieve the solar cell with enhanced efficiency.

In the embodiment as described above, since the distance between substrates can be maintained constant by providing the insulative partition wall 5 at the side of the silicon layer 4, the substrate is hardly bent even when the area of the substrate is large and a short circuit between electrodes nipping the silicon layer 4 can be prevented. In addition, the silicon layer 4 is protected by the insulative partition wall 5 and the deformation can be prevented, hereby improving the mechanical strength of the solar cell. Consequently, the highly reliable solar cell with a large area can be achieved.

[Method for Manufacturing Solar Cell]

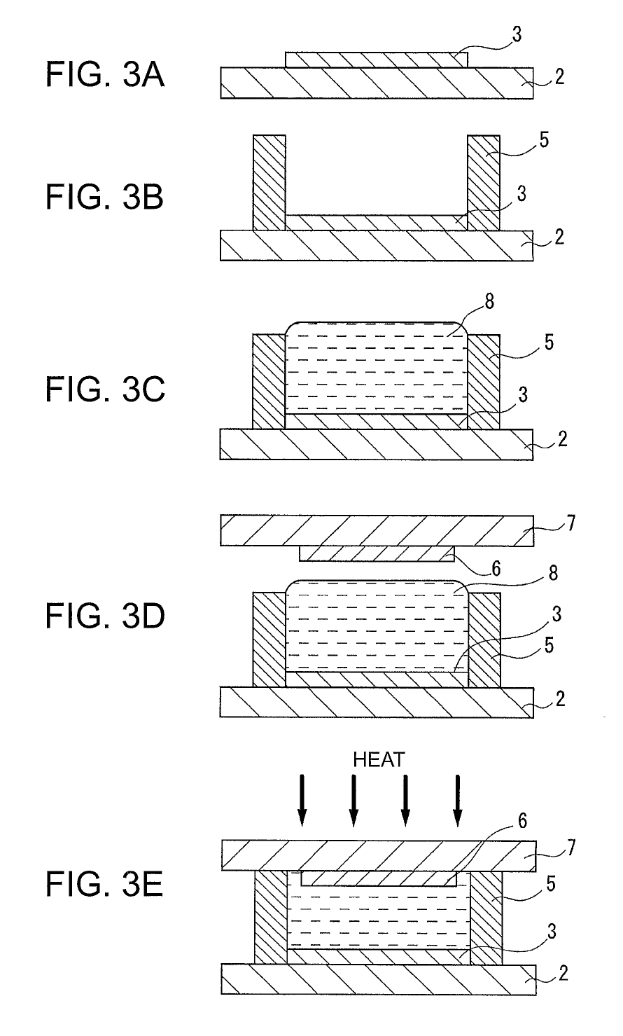

Next, an embodiment of a method for manufacturing the solar cell 1 described above is explained below with reference to FIGS. 3A through 3E. The FIGS. 3A through 3E are process diagrams indicating the method for manufacturing the solar cell 1 and correspond to the cross-section view of the solar cell 1 shown in FIG. 1. The embodiment described below is shown by way of an example, and able to be modified within the scope of the invention according to a designing demand or the like. Note that in order to facilitate the explanation of each structure or process, the scale and the number of components in each structure are different from those of an actual structure in the drawings below.

First, the substrate 2 to be the support of the solar cell 1 is prepared. As shown in FIG. 3A, the conductive film 3 to be the cathode is formed on the substrate 2. There is no particular limitation on the method for forming the conductive film 3 on the substrate 2. However, as Pt is used for the conductive film 3 in this embodiment, a Pt film is formed on the glass substrate 2 by sputtering, and patterning is then applied thereon to form the cathode.

Next, after an insulative material layer is formed by a layer thickness not less than 1 μm so as to cover the top faces of the substrate 2 and the conductive film 3, patterning is applied to the insulative material layer by a photolithography method to form the insulative partition wall 5 so as to surround the side face of the conductive film 3 as shown in FIG. 3B.

As a result, a region surrounded by the insulative partition wall 5 is formed on the substrate 2. At that time, the height of the insulative partition wall 5 is made to be a total of the film thickness of the silicon layer to be formed, the film thickness of the conductive film 3 and the film thickness of the transparent conductive film 6. By adjusting the height of the insulative partition wall 5, the film thickness of the silicon layer 4 to be formed later can be readily controlled.

As shown in FIG. 3C, a liquid silicon composition 8 is injected to the region of the substrate 2 partitioned by the insulative partition wall 5. The amount of the injected liquid silicon composition 8 is roughly matched with an amount corresponding to the height of the insulative partition wall 5, thereby controlling the film thickness of the silicon layer 4 by using the insulative partition wall 5.

While there is no particular limitation on the method of injecting the liquid silicon composition 8, it is possible to use a contact type printing method represented by a silk screen printing or gravure printing method and a non-contact type injection and printing method represented by a dispenser or inkjet method (liquid droplet discharge method). Particularly, with the use of inkjet method, the liquid silicon composition 8 can be subjected to the patterning directly and in a non-contact manner so that a necessary, minimum amount of the liquid silicon composition 8 is used for a necessary region, thereby extremely saving resources and preferably providing the simple, inexpensive solar cell 1.

The liquid silicon composition 8 in the embodiment is used for forming the silicon layer 4 which functions as a light reception layer of the solar cell 1. The silicon composition 8 is a liquid precursor composition which becomes a silicon thin film when it is heated. More specifically, the liquid silicon composition 8 is a mixture of polysilane indicated by a chemical formula: —(SiH₂)ₙ—, cyclopentasilane (hereinafter referred to as CPS) indicated by a chemical formula: —(Si₅H₁₀)—, and an organic solvent. While polysilane is in a solid and insoluble to most of the organic solvents, it is soluble to the CPS of the precursor of polysilane so that the polysilane is dissolved in a solvent which is mixture of the CPS and the organic solvent to form the liquid silicon composition 8.

Various methods for treating the liquid silicon composition 8 are conceivable. For example, one is described below. After the CPS is refined, it is irradiated with ultraviolet rays to generate photo polymerization, and then the irradiation by the ultraviolet rays is stopped before completion of the photo polymerization. When the CPS in an achromatic liquid at room temperature is irradiated with ultraviolet rays with a wavelength of, e.g., 405 nm, the CPS becomes polysilane in a white solid by virtue of ring-opening polymerization to form a state in which the polysilane with an average molecular mass of 2600 and a wide molecular mass distribution is dissolved in the nonreacted CPS. While the liquid is diluted by an organic solvent such as toluene, an insoluble matter is generated so that the insoluble matter is removed by means of a filter to form finally the liquid silicon composition 8.

Since the liquid silicon composition 8 is needed to be converted to high-purity silicon, it is preferable that the composition 8 does not include carbon and oxygen. By conveniently controlling a structure of the liquid silicon composition 8 and a heating condition in the event of converting the liquid silicon composition 8 to the silicon layer 4, it is possible to form the silicon layer 4 which has an extremely low content of carbon and oxygen and sufficiently functions as a semiconductor layer of the solar cell.

Next, in addition to the above processes, the transparent substrate 7 is prepared and the transparent conductive film 6 is formed on one face of the transparent substrate 7. Anyone of well known various methods can be used for the above process. As shown in FIG. 3D, the transparent substrate 7 is placed on the liquid silicon composition 8 so as to allow the transparent conductive film 6 and the conductive film 3 to be opposed with each other.

After that, the above components are subjected to the heat treatment to convert the liquid silicon composition 8 to the silicon layer 4. The transparent substrate 7 at the upper side in the drawing is fixed to the silicon layer 4 to form the solar cell 1 of the embodiment as shown in FIG. 1. The condition of the heat treatment is, for example, 120 minutes in the atmosphere of nitrogen with a residual oxygen concentration not greater than 0.5 ppm at temperature in a range of 200 to 400° C., preferably 350° C. Thus, by controlling the condition as the above, the content of carbon and oxygen in the silicon layer 4 can be reduced.

In the condition of the heat treatment, after the organic solvent in the liquid silicon composition 8 is firstly volatilized, Si—Si bonds with bonding energy of 224 kJ/mol are cut so that components in the form of SiH₂ and SiH₃ are separated. Next, Si—H bonds with bonding energy of 318 kJ/mol are cut, and then the silicon layer 4 is formed by remaining Si atoms. As a result, although the organic solvent is involved in the liquid silicon composition 8, it is possible to obtain the silicon layer 4 superior in a semiconductor characteristic having an extremely small quantity of carbon and oxygen. If quenching is carried out in a cooling process after the heat treatment, interfacial debonding due to a difference in a coefficient of thermal expansion tends to occur so that the temperature is gradually lowered in a rate of 5° C. or less per minute in the cooling.

As described above, according to the method for manufacturing of the embodiment, by forming the silicon layer 4 in the liquid process, it is possible to manufacture the highly efficient solar cell with the large area in low energy at low cost in a high throughput manner.

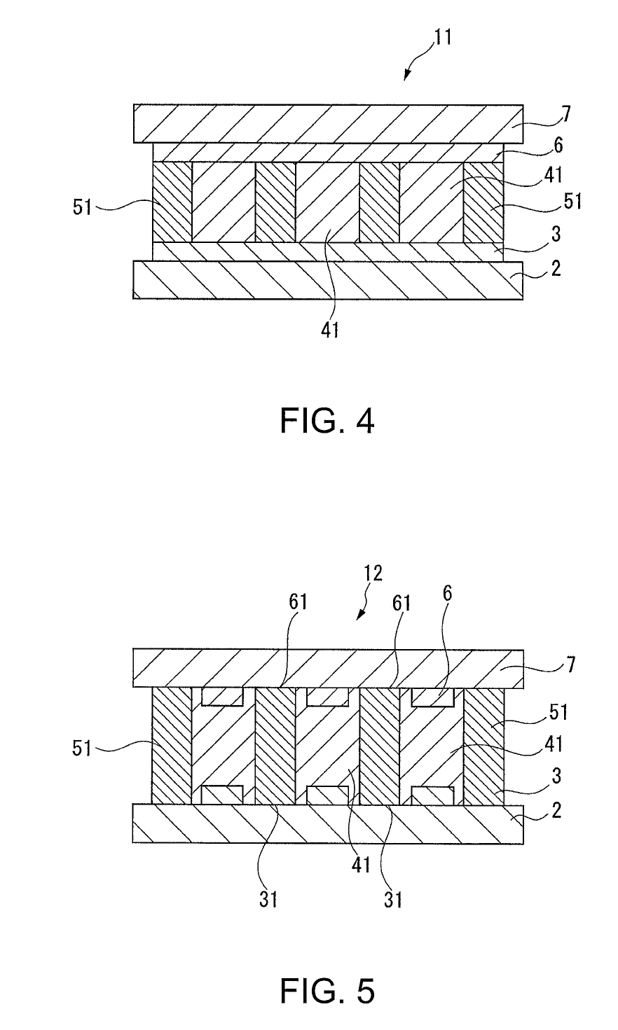

FIG. 4 and FIG. 5 are schematic cross-sectional views of second and third embodiments of a solar cell produced by the manufacturing method according to the invention. A point of each of the second and third embodiments different from the first embodiment is that a plurality of insulative partition wall arrays 51 are provided. The silicon layer 4 is divided into a plurality of small compartments 41 by insulative partition wall arrays 51.

A solar cell 11 according to the second embodiment shown in FIG. 4 is formed such that after the plurality of insulative partition wall arrays 51 are provided on the conductive film 3 formed on the substrate 2, the liquid silicon composition 8 is injected to each of regions surrounded by the respective insulative partition wall arrays 51. The transparent substrate 7 is placed on the liquid silicon composition 8, and then heat treatment is applied thereto to form the silicon layer 4 constituted of the small compartments 41.

FIG. 5 is a schematic cross-sectional view of the third embodiment of a solar cell formed by the manufacturing method of the invention. A point of the third embodiment different from the second embodiment is that grooves 31 and 61 are provided to the conductive film 3 and the transparent conductive film 6, respectively. The insulative partition wall arrays 51 are provided in the grooves 31 and 61. The grooves 31 and 61 are formed such that after the conductive film 3 and transparent conductive film 6 are formed, each of the films is subjected to patterning by a photo lithography method.

Since the plurality of insulative partition wall arrays 51 are provided as in the third embodiment shown in FIG. 4 and the fourth embodiment shown in FIG. 5, even when areas or the solar cells 11 and 12 are enlarged, the insulative partition wall arrays 51 serve as spacers for supporting the silicon layer 4 in the layer thickness direction. As a result, it is possible to prevent a short circuit due to contact of the conductive film 3 with the transparent conductive film 6, thereby providing the highly reliable solar cell 11.

By providing the plurality of insulative partition wall arrays 51, the mechanical strength of the silicon layer 4 is increased so that it is possible to prevent bending of the solar cell 11 with the large area due to its own weight, thereby improving the reliability of the solar cell 11.

The entire disclosure of Japanese Patent Application No. 2008-060860, filed Mar. 11, 2008 is expressly incorporated by reference herein.

What is claimed is:

1. A solar cell comprising:
a substrate;
a conductive film formed on the substrate;
a transparent substrate;
a transparent conductive film formed on the transparent substrate;
a silicon layer nipped between the conductive films and the transparent conductive film; and
an insulative partition wall provided between the substrate and the transparent substrate to surround a side face of the silicon layer,
wherein the conductive film has a first work function which is greater than a Fermi level of the silicon layer, and
wherein the transparent conductive film has a second work function which is smaller than a Fermi level of the silicon layer.

2. A method for manufacturing a solar cell comprising:
forming a conductive film on a first face of a substrate;
forming an insulative partition wall so as to surround a peripheral edge of the conductive film;
injecting a liquid silicon composition in a region surrounded by the insulative partition wall on the first face of the substrate;
forming a transparent conductive film on a second face of a transparent substrate;
placing the transparent substrate on the liquid silicon composition so as to allow the transparent conductive film to be opposed to the conductive film; and
heating the liquid silicon composition.

3. The method for manufacturing a solar cell according to claim 2, wherein a metallic material having a high reflectivity and a work function which is greater than a Fermi level of a silicon layer formed by solidifying the liquid silicon composition, is used as the conductive film.

4. The method for manufacturing a solar cell according to claim 2, wherein a material having a band gap of 1 eV or more and a work function which is smaller than a Fermi level of a silicon layer formed by solidifying the liquid silicon composition, is used as the transparent conductive film.

5. The method for manufacturing a solar cell according to claim 2, wherein a droplet discharge method is used in the event of injecting the liquid silicon composition.
